(19) United States
(12) Patent Application Publication
(10) Pub. No.: US 2009/0017583 A1
(43) Pub. Date: Jan. 15, 2009

(54) DOUBLE ENCAPSULATED SEMICONDUCTOR PACKAGE AND MANUFACTURING METHOD THEREOF

(75) Inventors: Byung-Seok JUN, Chungcheongnam-do (KR); Gil-Beag KIM, Chungcheongnam-do (KR); Yong-Jin LEE, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/237,273

(22) Filed: Sep. 24, 2008

Related U.S. Application Data
(62) Division of application No. 11/464,359, filed on Aug. 14, 2006.

(30) Foreign Application Priority Data
Jan. 16, 2006 (KR) 2006-4298

(51) Int. Cl. H01L 21/56

(52) U.S. Cl. 438/127; 257/E21.502

(57) ABSTRACT

A double encapsulated semiconductor package and manufacturing methods of forming the same are provided. Embodiments of the semiconductor package include a complex chip having normal and random pads formed on its active surface, the complex chip being attached to a first surface of a wiring substrate. First and second windows are formed in the wiring substrate to respectively expose the normal and random pads, and to allow bonding wires to be connected to the normal and random pads with the wiring substrate. A first resin encapsulation portion is formed by a molding method in the first window and a second resin encapsulation portion is formed by a potting method in the second window.

### CROSS-REFERENCE TO RELATED PATENT APPLICATION

This application is a Divisional of U.S. Ser. No. 11/464,359, filed on Aug. 14, 2006, now pending, which claims priority from Korean Patent Application No. 2006-4298, filed on Jan. 16, 2006, all of which are hereby incorporated by reference in their entirety.

### BACKGROUND

1. Field of the Invention

The present invention relates to a semiconductor package, and more particularly, to a semiconductor package and a manufacturing method thereof having resin encapsulation portions formed at both sides of a wiring substrate.

2. Description of the Prior Art

In the current market of electronic products demand for mobile electronic products is rapidly increasing, and miniaturization of parts used in the electronic products is essential for satisfying this demand. A technology for reducing the size of an individual semiconductor package installed as a part, a system on chip (SOC) technology making a plurality of semiconductor chips into one chip, or a system in package (SIP) technology integrating a plurality of individual semiconductor chips into a package may be necessary to accomplish this miniaturization.

In the case of SOC, chip pad arrangement may include a random arrangement type, where chip pads are formed in a random area of an active surface, and general arrangement types of chip pads, such as an edge pad type or a center pad type. Additionally, a semiconductor chip including the random arrangement type may exist in the semiconductor chips utilizing the SIP technology.

Hereafter, a chip pad in the general pad arrangement type is referred to as a ‘normal pad’, a chip pad in the random arrangement type is referred to as a ‘random pad’, a semiconductor chip having only normal pads is referred to as a ‘normal chip’, and a semiconductor chip including random pads is referred to as a ‘complex chip’.

FIG. 1 is a sectional view showing an example of a conventional semiconductor package installed with a complex chip. Referring to FIG. 1, a semiconductor package 100 having a complex chip 10 is attached on a wiring substrate 30 in a face-down form. That is, an active surface 12 of the complex chip 10 is attached to a first surface 31 of the wiring substrate 30. Normal pads 14 and random pads 16 of the complex chip 10 are exposed through first windows 35 and second windows 37, respectively, formed on the wiring substrate 30. The normal pads 14 and random pads 16 are electrically connected to the wiring substrate 30 by bonding wires 40 through the first windows 35 and the second windows 37. The complex chip 10 and the bonding wires 40 installed in the first windows 35 and the second windows 37 are protected from the external environment by resin encapsulation portions 51 and 53. Additionally, solder balls 60 are formed on a second surface 33 of the wiring substrate 30. This semiconductor package 100 is called a board on chip (BOC) package.

Additionally, a transfer molding method using a mold die is utilized to form the resin encapsulation portions 51 and 53 on both sides 31 and 33 of the wiring substrate 30. The resin encapsulation portions are divided into a first resin encapsulation portion 51 and a second resin encapsulation portion 53. The first resin encapsulation portion 51 encapsulates the first surface 31 and the first windows 35 of the second surface 33. The first resin encapsulation portion 51 is formed with molding resin in a liquid state injected through the first windows 35 or the first surface 31. Additionally, the second resin encapsulation portion 53 formed separately from the first resin encapsulation portion 51 encapsulates the second windows 37 of the wiring substrate 30, through which random pads 16 of the complex chip 10 are exposed.

In order to form the first resin encapsulation portion 51 and the second resin encapsulation portion 53 in a single molding step, injection of the molding resin in a liquid state must be performed separately. That is, a new mold die having a runner enabling injection of the molding resin in a liquid form separately into the first windows 35 and the second windows 37 is required.

In contrast to the first windows 35, the second windows 37 may be disposed in various forms and locations according to the areas where the random pads 16 are formed. Therefore additional costs may arise in manufacturing a mold die having a runner corresponding to the locations of the second windows 37.

### SUMMARY

An object of the present invention is to form a first and a second resin encapsulation portion without manufacturing a new mold die.

In order to achieve the above object, an embodiment of the present invention provides a double encapsulated semiconductor package in which an active surface of a complex chip is attached to a first surface of a wiring substrate. The complex chip includes a plurality of normal pads and random pads formed on the active surface. The wiring substrate includes the first and a second surface, and first windows and second windows, which are formed such that the normal pads and random pads, respectively, of the complex chip are exposed. The normal pads and random pads are electrically connected to the wiring substrate by bonding wires through the first windows and the second windows. A first resin encapsulation portion, formed by a molding method, covers the complex chip installed on the first surface and also covers the first windows of the second surface. A second resin encapsulation portion, formed by a potting method, covers the second windows of the second surface.

### BRIEF DESCRIPTION OF THE DRAWINGS

FIG. 1 is a sectional view showing an example of a conventional semiconductor package installed with a complex chip.

FIG. 2 is a plan view showing a wiring substrate of a double encapsulated semiconductor package according to a first example embodiment of the present invention.

FIG. 3 is a plan view showing the double encapsulated semiconductor package according to the first example embodiment of the present invention.

FIG. 4 is a sectional view taken along the line IV-IV of FIG. 3.

FIGS. 5 to 7 are views showing a method of a manufacturing the semiconductor package illustrated in FIG. 3.

FIG. 8 is a sectional view showing a double encapsulated semiconductor package according to a second example embodiment of the present invention.

FIG. 9 is a sectional view showing a double encapsulated semiconductor package according to a third example embodiment of the present invention.

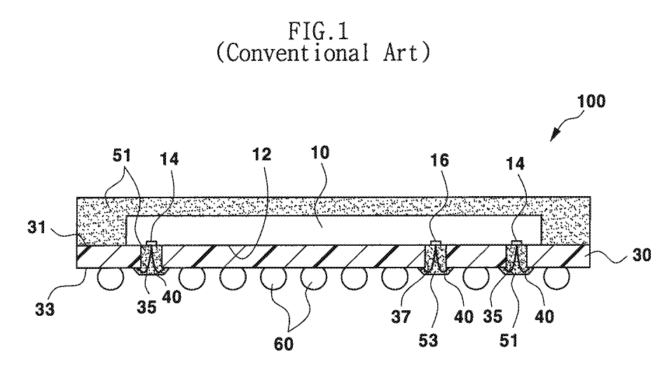

### DETAILED DESCRIPTION

Hereinafter, example embodiments of the present invention will be described in detail with reference to the accompanying drawings. Like reference numerals refer to similar elements in the drawings. Additionally, the drawings may not be to scale and some layers may be exaggerated for the sake of clarity.

### Example 1

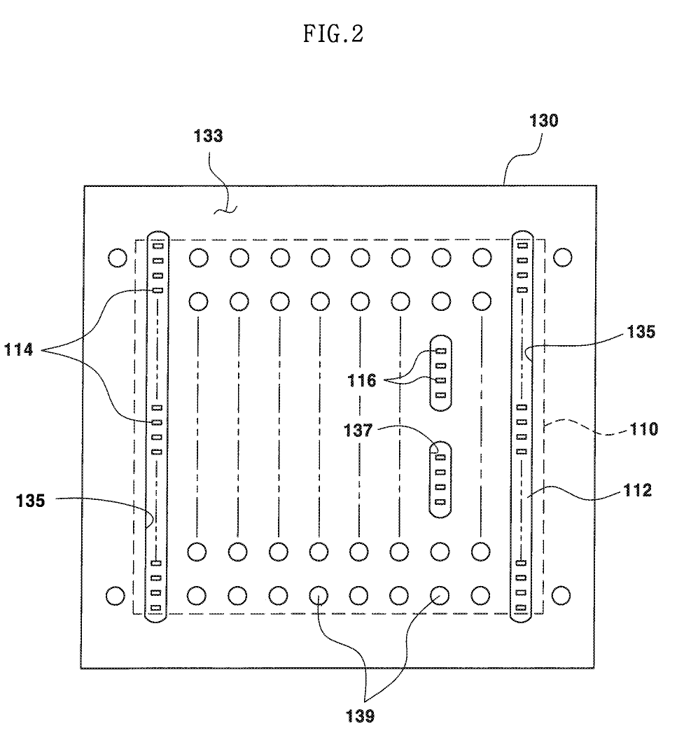

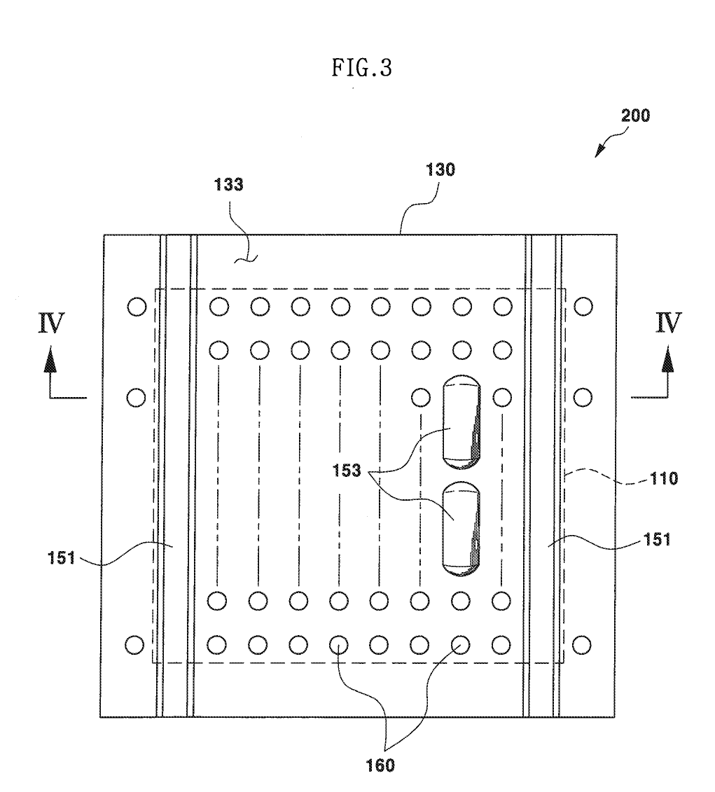

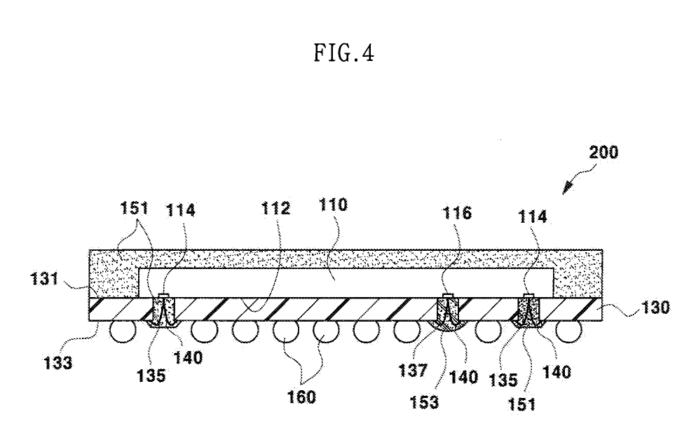

FIG. 2 is a plan view showing a wiring substrate 130 of a double encapsulated semiconductor chip according to a first example embodiment of the present invention. FIG. 3 is a plan view showing the double encapsulated semiconductor package 200 according to the first example embodiment of the present invention. FIG. 4 is a sectional view taken along the line IV-IV of FIG. 3.

Referring to FIGS. 2 to 4, the semiconductor package 200 according to the first example embodiment of the present invention is a BOC package in which a complex chip 110 is attached to the wiring substrate 130 in a face-down form.

The complex chip 110 includes normal pads 114 that may be formed at both sides of an active surface 112 and random pads 116 that may be formed at an inner area of the active surface 112. The normal pads 114 may be formed at both sides parallel to each other and the random pads 116 may be formed in two groups that maintain a predetermined distance between each other.

The wiring substrate 130 has a first surface 131 and a second surface 133 opposite to the first surface 131. The active surface 112 of the complex chip 110 may be attached to the first surface 131, and first windows 135 and second windows 137 may be formed such that the normal pads 114 and the random pads 116 are exposed, respectively. The first windows 135 may be formed such that the first window covers the edges of the complex chip 110 formed with the normal pads 114.

In particular, the length of the first windows 135 may be formed to be larger than the length of the complex chip 110 formed with the normal pads 114 so that epoxy resin in a liquid form may move towards the first surface 131 or the second surface 133 through the first windows 135. Accordingly, both ends of the first windows 135 may be exposed outside of the area where the complex chip 110 is attached. The second windows 137 are formed such that the random pads 116 formed in two groups are exposed.

A printed circuit board, tape wiring substrate, ceramic wiring substrate, or silicon wiring substrate may be used as the wiring substrate 130.

The normal pads 114 and the random pads 116 may be connected to the wiring substrate 130 by bonding wires 140 through the first windows 135 and the second windows 137 of the wiring substrate 130.

The complex chip 110 and the bonding wires 140 installed in the first windows 135 and the second windows 137 may be protected from the external environment by a first resin encapsulation portion 151 and a second resin encapsulation portion 153, respectively. The first resin encapsulation portion 151 may encapsulate the complex chip 110 installed on the first surface 131 of the wiring substrate 130, and may encapsulate the first windows 135 and portions of the second surface 133. The second resin encapsulation portion 153 may encapsulate the second windows 137 of the wiring substrate 130.

Additionally, solder balls 160 for external connections are formed on ball pads 139 of the wiring substrate 130 not covered by the first resin encapsulation portion 151 and the second resin encapsulation portion 153. The solder balls 160 are formed relatively higher than the first resin encapsulation portion 151 and the second resin encapsulation portion 153 formed on the second surface 133.

In particular, the first resin encapsulation portion 151 may be formed by a molding method, and the second resin encapsulation portion 153 may be formed by a potting method. The first resin encapsulation portion 151 may include an epoxy resin material. The second resin encapsulation portion 153 may include a silicon resin material.

In the semiconductor package 200 according to the first embodiment of the present invention, the first resin encapsulation portion 151 may be formed by a conventional molding method and the second resin encapsulation portion 153 may be formed by a conventional potting method, using an existing mold die without having to manufacture a new mold die.

Hereinafter, a manufacturing method of a semiconductor package 200 according to the first example embodiment of the present invention is described in detail with reference to FIGS. 4 to 7.

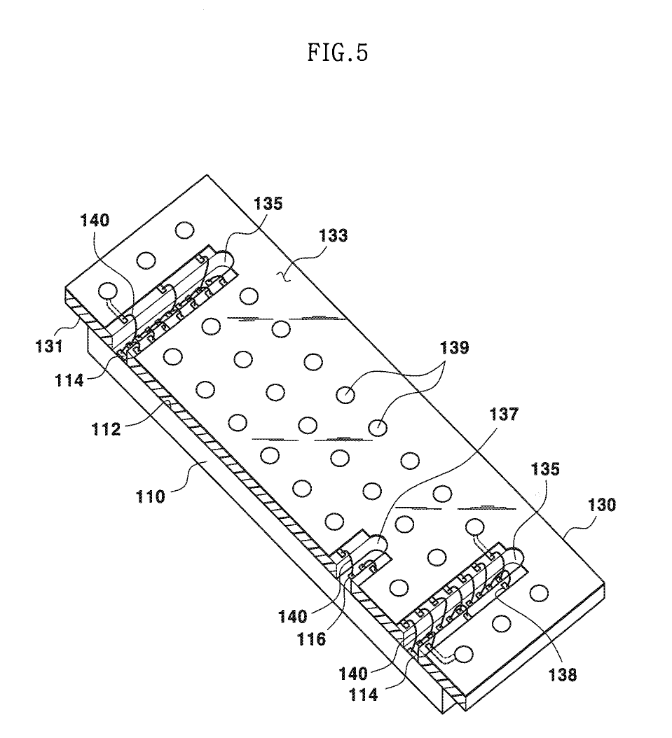

As shown in FIG. 5, the manufacturing method of the semiconductor package 200 begins with a step of preparing a complex chip 110. An active surface 112 of the complex chip 110 is attached to a first surface 131 of a wiring substrate 130. Normal pads 114 of the complex chip 110 are exposed towards a second surface 133 of the wiring substrate 130 through first windows 135, and random pads 116 of the complex chip 110 are exposed towards the second surface 133 of the wiring substrate 130 through second windows 137. Additionally, the normal pads 114 and the random pads 116 are electrically connected to substrate pads 138 of the wiring substrate 130 through the first windows 135 and second windows 137. The substrate pads 138 may individually connect to ball pads 139.

Although the method of manufacturing a single semiconductor package with the wiring substrate 130 is illustrated, a method of manufacturing a plurality of semiconductor packages simultaneously in a strip form may also be provided.

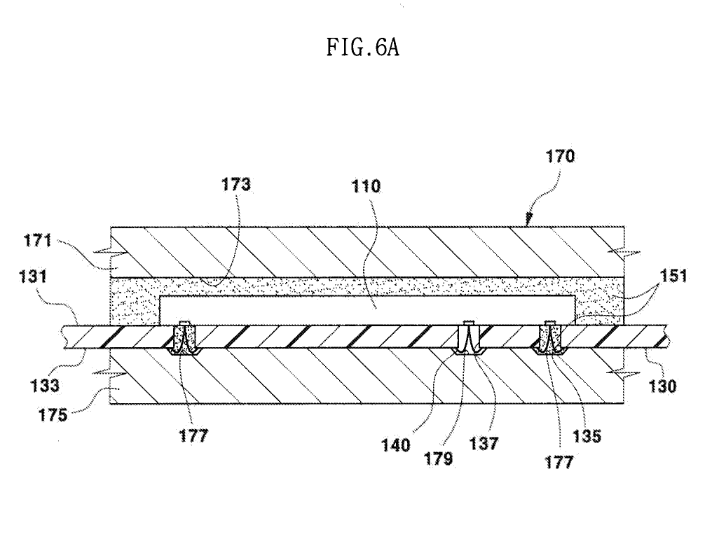

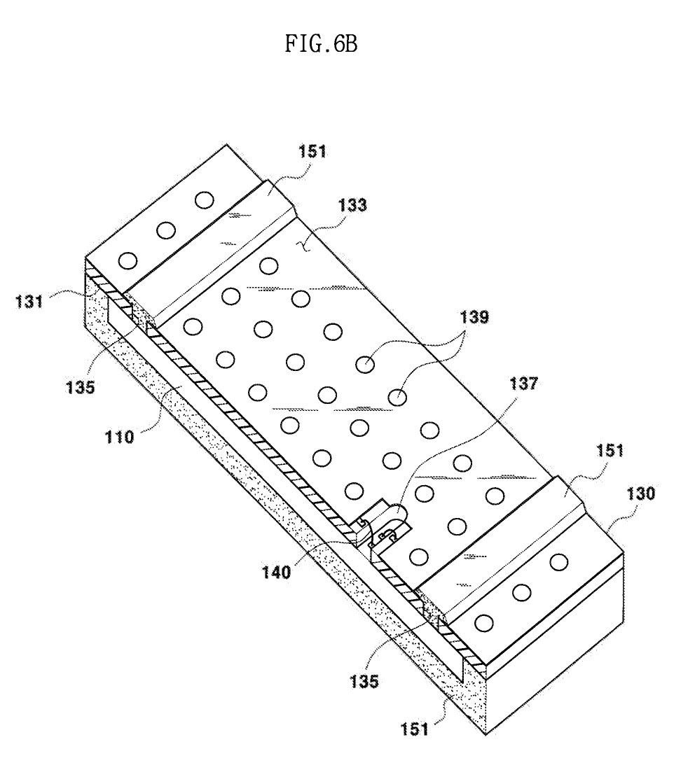

As shown in FIGS. 6A, 6B, and 7, a first resin encapsulation portion 151 and a second resin encapsulation portion 153 are formed by an encapsulating process in two steps.

First, as shown in FIGS. 6A and 6B, a step of forming the first resin encapsulation portion 151 is performed by encapsulating the complex chip 110 installed on the first surface 131 of the wiring substrate 130, the first windows 135, and portions of the second surface 133 of the wiring substrate 130 in a transfer molding method using a mold die 170. The wiring substrate 130 is transferred to a space between an upper mold 171 and a lower mold 175. The first resin encapsulation portion 151 is formed by injecting epoxy resin in a liquid state into cavities 173 and 177 when the upper mold 171 and the lower mold 175 are engaged with each other to fix the wiring substrate 130, to thereby encapsulate the complex chip 110 attached to the first surface 131 of the wiring substrate 130 and the first windows 135.

In particular, the first resin encapsulation portion 151 may be formed by injecting epoxy resin in a liquid state into the cavity 173 of the upper mold 171, passing the epoxy resin to the cavity 177 of the lower mold 175 through both ends of the first windows 135 not covered by the complex chip 110, and filling the cavities 173 and 177 of the mold die 170. Alternatively, the first resin encapsulation portion 151 may be formed by injecting epoxy resin in a liquid state into the cavity 177 of the lower mold 175, passing the epoxy resin to the cavity 173 of the upper mold 171 through the first windows 135, and filling the cavities 173 and 177 of the mold die 170.

In the step of forming the first resin encapsulation portion 151, a dummy cavity 179 may be formed at a portion of the lower mold 175 corresponding to the second windows 137 in order to protect the bonding wires 140 formed in the second windows 137 from being damaged by the lower mold 175. The dummy cavity is preferably formed in a size sufficient to cover the second windows 137 and the bonding wires 140.

Subsequently, as shown in FIG. 7, a step of forming a second resin encapsulation portion 153 is performed by encapsulating the second windows 137 of the wiring substrate 130 using a potting method. The second resin encapsulation portion 153 may be formed by encapsulating the second windows 137 exposed towards the second surface 133 of the wiring substrate 130 with a silicon based resin (i.e., a resin of a silicon family) in a potting method using a syringe 180. The second resin encapsulation portion 153 is formed as an island on the second surface 133 of the wiring substrate 130.

Particularly, by forming the second resin encapsulation portion 153 by a potting method, the process of forming the second resin encapsulation portion 153 may be performed regardless of the locations of the second windows 137 formed on the wiring substrate 130, because the syringe 180 performing the potting process may easily be moved to the locations of the second windows 137 of the wiring substrate 130.

Lastly, a semiconductor package 200 (shown in FIG. 4) may be obtained by performing a step of forming solder balls 160 on the ball pads 139 (shown in FIG. 7) of the wiring substrate 130. The solder balls 160 may be formed by applying flux to the ball pads 139, laying the solder balls onto the ball pads, and reflowing. Nickel or gold bumps may also be used instead of the solder balls 160.

In the case where the wiring substrate 130 is provided in a strip form, a step of separating individual semiconductor packages 200 may further be performed by using a cutter.

In the semiconductor package 200 according to the first embodiment of the present invention, the first resin encapsulation portion 151 may be formed by a conventional molding method and the second resin encapsulation portion 153 may be formed by a conventional potting method, using an existing mold die without having to manufacture a new mold die.

### Example 2

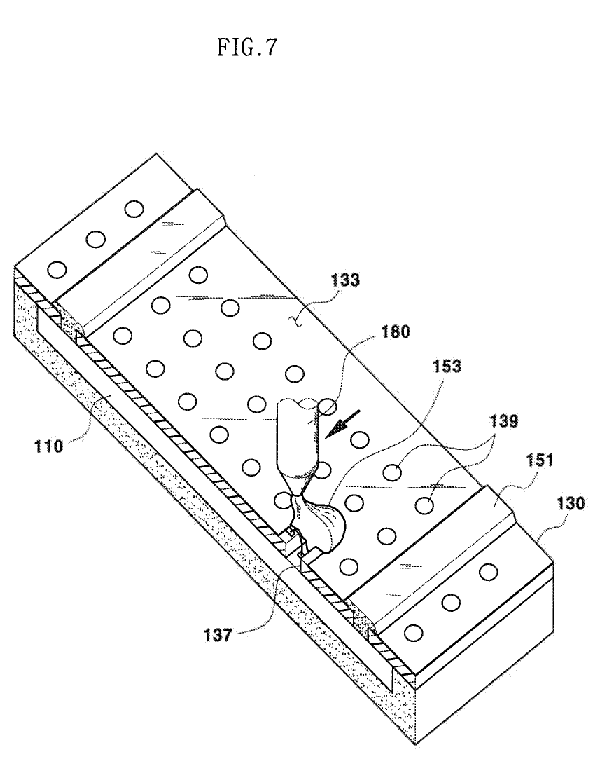

Although, in the first example embodiment of the present invention, an example where normal pads of a complex chip are formed in an edge pad type is illustrated, the normal pads may also be formed in a center pad type as shown in FIG. 8. A semiconductor package 300 according to a second example embodiment of the present invention has the same structure as that of the first example embodiment from the viewpoint that a complex chip 210 is attached to a first surface 231 of a wiring substrate 230 in a face-down manner.

Normal pads 214 of the complex chip 210 are formed at a center area of an active surface 212, and random pads 216 of the complex chip 210 are formed outside the center area of the active surface 212. First windows 235 and second windows 237 are formed such that the first windows 235 and second windows 237 correspond to the normal pads 214 and the random pads 216 of the complex chip 210, respectively, in the wiring substrate 230. Additionally, a first resin encapsulation portion 251 is formed by a molding method, and a second resin encapsulation portion 253 is formed by a potting method.

Although, in the second example embodiment of the present invention, an example of forming the normal pads 214 at the center and the random pad 216 at both sides is illustrated, this example embodiment is not limited thereto. As another complex chip, a semiconductor chip having normal pads formed at the center area and both sides of the active surface may also be used. The random pads are formed at an area of the active surface outside the area in which the normal pads are formed.

### Example 3

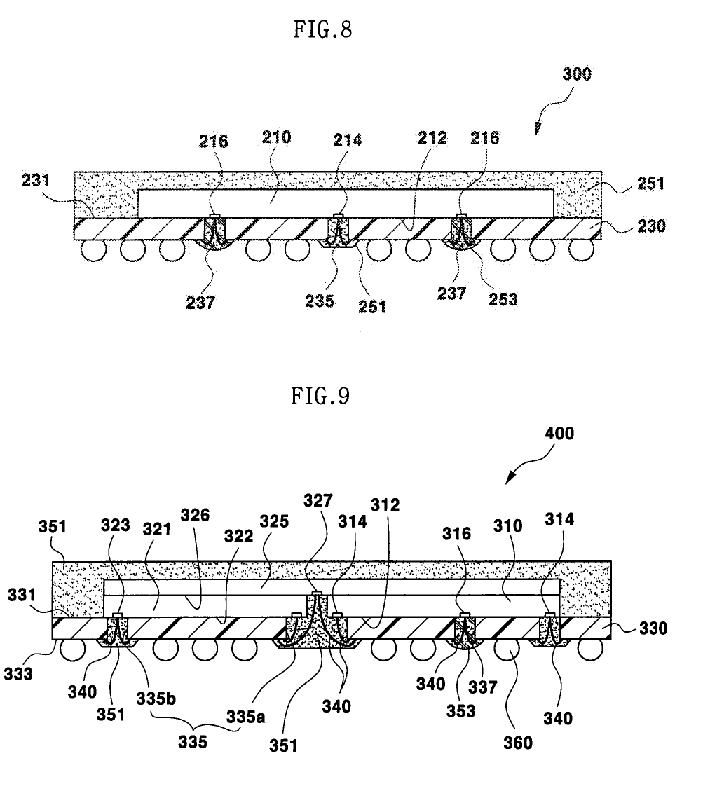

Although, in the first and second example embodiments of the present invention, examples of semiconductor package installed with a single complex chip have been illustrated, a semiconductor package 400 installed with normal chips 321 and 325, and a complex chip 310 may be provided in a multi-chip form as shown in FIG. 9.

The semiconductor package 400 according to a third example embodiment of the present invention is a multi-chip package having a first normal chip 321 and a complex chip 310 installed horizontally on a first surface 331 of a wiring substrate 330, and a normal chip 325 vertically stacked on the first normal chip 321 and the complex chip 310.

The complex chip 310 and the first normal chip 321 are attached on the first surface 331 of the wiring substrate 330 maintaining a predetermined distance between each other. The first normal chip 321 mat be a semiconductor chip with an edge pad type formed with normal pads 323 at both sides of an active surface 322. The complex chip 310 may include normal pads 314 formed at both sides of the active surface 312 and random pads 316 formed at an inner area between both sides at which the normal pads 314 are formed. The normal pads 323 of the first normal chip 321 and normal pads 314 of the complex chip 310 are substantially formed parallel to each other.

First windows 335 are formed on the wiring substrate 330 such that normal pads 314 and 323 of the complex chip 310 and the first normal chip 321 are exposed, and second windows 337 are formed on the wiring substrate 330 such that random pads 316 of the complex chip 310 are exposed. The first windows 335 include a center window 335a, through which adjacent normal pads 314 and 323 of the complex chip 310 and the first normal chip 321 are respectively exposed together, and outer windows through which the remaining normal pads 314 and 323 of the complex chip 310 and the first normal chip 321 are respectively exposed. The center window 335a and outer windows 335b may be substantially formed parallel to each other.

A second normal chip 325 is stacked on the complex chip 310 and the first normal chip 321. That is, an active surface 326 of the second normal chip 325 is attached to rear surfaces of the complex chip 310 and the first normal chip 321. The second normal chip 325 may be a semiconductor chip of a center pad type having normal pads 327 formed at the center of its active surface 326, where the normal pads 327 may be exposed through a space between the complex chip 310 and the first normal chip 321. That is, the normal pads 327 of the second normal chip 325 may be exposed through the center window 335a.

The complex chip 310 and the first normal chip 321 are preferably formed to be about the same thickness such that the second normal chip 325 may be stably attached to the rear surfaces of the complex chip 310 and the first normal chip 321.

The normal pads 314, 323, and 327 and the random pads 316 exposed respectively through the first windows 335 and second windows 337 of the wiring substrate 330 are electrically connected to the wiring substrate 330 by bonding wires 340.

A first resin encapsulation portion 351 is formed by a molding method, and protects the semiconductor chips 310, 321, and 325 installed on the first surface 331 of the wiring substrate 330, the first windows 335, and a portion the second surface 333 from the external environment. A second resin encapsulation portion 353 is formed by a potting method, and protects the second windows 337 of the wiring substrate 330 from the external environment.

Additionally, solder balls 360 may be formed on the second surface 333 of the wiring substrate 330 not covered by the first resin encapsulation portion 351 and second resin encapsulation portion 353. The solder balls 360 may be formed to be relatively higher than the first resin encapsulation portion 351 and the second resin encapsulation portion 353 formed on the second surface 333.

Although, in the third example embodiment, an example of installing a complex chip 310 and the normal chips 321 and 325 on a wiring substrate in the horizontal and vertical directions has been illustrated, the present invention is not limited thereto. For example, a complex chip and a normal chip may be installed on the first surface of the wiring substrate only in the horizontal direction. Alternatively, the complex chip and the normal chip may be stacked only in the vertical direction.

Additionally, although an example of installing a complex chip 310 on a wiring substrate 330 has been illustrated, the present invention is not limited thereto, and more than one complex chip may be installed on the wiring substrate in the horizontal direction.

Therefore, according to the present invention, resin encapsulation portions may be formed without manufacturing a new mold die, because semiconductor chips including a complex chip installed on a first surface of a wiring substrate having normal pads exposed through first windows in the wiring substrate are protected by a first resin encapsulation portion formed by a molding method, and random pads exposed through second windows of the wiring substrate are protected by a second resin encapsulation portion formed by a potting method.

Accordingly, the encapsulating process may be performed regardless of the locations of the second windows of the wiring substrate, because the second resin encapsulation portion is formed by a potting method.

Although example embodiments of the present invention have been described in detail hereinabove, it should be understood that many variations and/or modifications of the basic inventive concept herein described, which may appear to those skilled in the art, will still fall within the spirit and scope of the example embodiments of the present invention as defined in the appended claims.

What is claimed is:

1. A manufacturing method of a semiconductor chip package comprising:
(a) providing a complex chip having an active surface, the complex chip including normal pads and random pads formed on the active surface of the complex chip;
(b) attaching the active surface of the complex chip on a first surface of a wiring substrate such that the normal pads are exposed through first windows of the wiring substrate and the random pads are exposed through second windows of the wiring substrate;
(c) electrically connecting the normal and random pads to the wiring substrate with bonding wires through the first and second windows, respectively;
(d) forming a first resin encapsulation portion by substantially simultaneously encapsulating the semiconductor chip installed on the first surface of the wiring substrate and substantially filling the first windows formed through the wiring substrate in a molding method;
(e) forming a second resin encapsulation portion by substantially filling the second windows formed through the wiring substrate in a potting method; and
(f) forming solder balls on the second surface.

2. The method of claim 1, wherein the step (d) is performed by a transfer molding method using an epoxy resin.

3. The method of claim 2, wherein the step (e) is performed by a potting method using a silicon based resin.

4. A manufacturing method of a semiconductor chip package comprising:
(a) providing semiconductor chips including a normal chip formed with normal pads on its active surface and a complex chip formed with normal pads and random pads on its active surface;
(b) attaching the active surface of at least one of the semiconductor chips on a first surface of a wiring substrate such that the normal pads are exposed through first windows of the wiring substrate and the random pads are exposed through second windows of the wiring substrate;
(c) electrically connecting the normal and random pads to the wiring substrate with bonding wires through the first and second windows, respectively;
(d) forming a first resin encapsulation portion to substantially simultaneously cover the semiconductor chips installed on the first surface and the first windows by a molding method;
(e) forming a second resin encapsulation portion to cover the second windows by a potting method; and
(f) forming solder balls on the second surface.

5. The method of claim 4, wherein the step (d) is performed by a transfer molding method using an epoxy resin.

6. The method of claim 5, wherein the step (e) is performed by a potting method using a silicon based resin.

7. A method of manufacturing a semiconductor chip package comprising:
attaching a complex semiconductor chip having an active surface and including normal pads and random pads formed on the active surface to a first surface of a wiring substrate including first and second windows, where the normal pads and random pads are respectively exposed through the first and second windows of the wiring substrate;
electrically connecting the normal pads and random pads of the complex semiconductor chip to a second surface of the wiring substrate through the first and second windows, respectively;
performing a molding encapsulation process to form a first resin encapsulation portion over the complex semiconductor chip and substantially filling the first windows;
performing a potting encapsulation process to form a second resin encapsulation portion substantially filling the second windows; and
forming solder balls on the second surface of the wiring substrate.

8. The method of claim 7, wherein the molding encapsulation process includes:
transferring the wiring substrate having the attached complex semiconductor chip to a die mold including an upper mold and a lower mold, where the upper and lower molds include cavities;
engaging the upper and lower molds; and
injecting resin into the cavities of the upper and lower molds to form the first resin encapsulation portion over the complex semiconductor chip and substantially filling the first windows.

9. The method of claim 8, wherein the first window formed through the wiring substrate extends past at least one edge of the complex semiconductor chip such that when resin is injected into the cavity formed in the upper mold the resin will travel to the cavity formed in the lower mold, or when resin is injected into the cavity formed in the lower mold the resin will travel to the cavity formed in the upper mold.

10. The method of claim 7, wherein the potting encapsulation process includes providing resin through a syringe on the second surface of the wiring substrate to form an island of resin substantially filling the second window.
